(19) United States
(12) Patent Application Publication
(10) Pub. No.: US 2009/0186191 A1
(43) Pub. Date: Jul. 23, 2009

(54) Method of making a transparent metal oxide coated glass panel for photovoltaic module

(76) Inventor: Peter Lechner, Vaterstetten (DE)

Correspondence Address: FLYNN THIEL BOUTELL & TANIS, P.C., 2026 RAMBLING ROAD, KALAMAZOO, MI, 49008-1631, US

(21) Appl. No.: 12/321,004

(22) Filed: Jan. 14, 2009

(30) Foreign Application Priority Data
Jan. 19, 2008 (DE) 10 2008 005 283.3

(51) Int. Cl. B05D 5/12; C23C 16/44; B32B 17/06; C23C 16/40

(52) U.S. Cl. 428/141; 427/585; 428/432; 118/715

(57) ABSTRACT

For making a glass panel (1) coated by chemical vapour deposition with an electrically conductive transparent metal oxide (3) for use as a starting material for fabricating a photovoltaic module, chemical vapour deposition of said electrically conductive transparent metal oxide (3) onto glass panel (1) is performed at a coating temperature not more than 50° C. lower than the transition temperature of the glass.

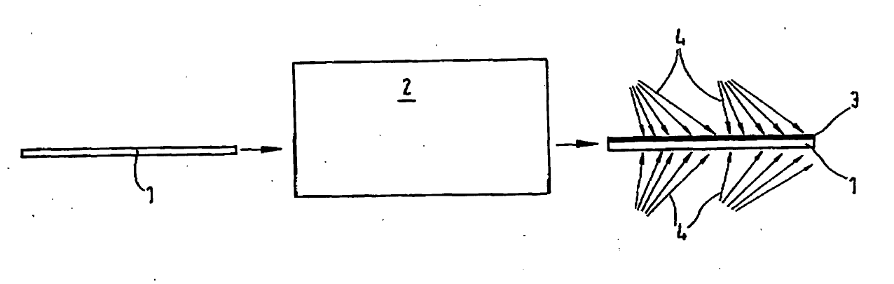

The present invention relates to a method of making a glass panel coated by chemical vapour deposition with an electrically conductive transparent metal oxide for use as a starting material for a photovoltaic module. It also relates to such a glass panel coated with a electrically conductive transparent metal oxide, as well as to a plant for performing said method.

Photovoltaic modules comprise a transparent substrate (mostly a glass panel) having a front electrode layer consisting of a electrically conductive transparent metal oxide (TCO; frequently tin oxide), a semi conducting layer (such as silicon) on said front electrode layer, as well as a rear metal electrode layer.

The photovoltaic module generally consists of cells series-connected by connecting the rear electrode layer of one cell with the front electrode layer of the adjacent cell. To this end, means such as a laser beam are used to form separating lines normal to the direction of current flow. In addition, the module is provided frequently with terminals and a rear surface protective guard, which may be another glass panel or a plastic film.

The starting material to be coated with the semiconductor and rear electrode layers is a glass panel coated by chemical vapour deposition at atmospheric pressure (APCVD).

Where the APCVD process is incorporated in the continuous process of making float glass, the method is referred to also as “on-line” APCVD. In that case, the sources of the coating materials are positioned within the float glass making plant in an area where the glass temperature is about 550° C. to 700° C. Thereafter, the glass ribbon is cooled very slowly and in a well-defined manner to maintain the glass as free of stress as possible.

In contrast, glass panels cut to their final size are coated with the electrically conductive transparent metal oxide in a coating plant of their own in accordance with the “off-line” APCVD method in which the glass panels are heated prior to coating to about 450° C. or 550° C. in a heating zone. Thereafter, the glass panels coated with the electrically conductive transparent metal oxide are cooled slowly and in a well-defined manner so as to be as free of stress as possible.

In numerous applications of a photovoltaic module, requirements in use to mechanical strength (under high snow loads, for example) or to stability under fluctuating thermal loads (partial shadowing or sliding snow, for example) are stringent. Glass panels coated in accordance with the on-line or off-line APCVD method frequently cannot meet these requirements as their flexural strength is a mere 45 N/mm² and their thermal fatigue resistance a mere 40 K (EN 572-1). As a result, a considerably danger of fracture of the photovoltaic module exists in use on a roof or in the field, for example, but also during manufacture, shipment or installation. In such cases of damage, warranty claims may dramatically affect the producer of the photovoltaic module.

In order to minimize such dangers, the glass panel coated with the electrically conductive transparent metal oxide in accordance with the on-line or off-line APCVD method may be thermally or chemically pre-stressed or strengthened in a further separate process step prior to being processed for forming a photovoltaic module. This way, the panel attains the desired mechanical strength and thermal loading capacity.

In conventional thermal pre-stressing, the glass panel coated on-line or off-line by the APCVD method is turned into single-layer safety glass having a flexural strength higher than 120 N/mm² (EN 12150-1) or into a partly pre-stressed glass having a flexural strength higher than 70 N/mm² (EN 1863-1) as determined by test standard EN 1288-3.

The thermal pre-stressing requires additional effort, however, and thus increased costs. Another drawback of thermal pre-stressing is a more or less pronounced waviness or ripple of the glass panel of up to 3 mm per 1000 mm (“general distortion”) or of 0.3 mm per 300 mm (“local distortion”). This ripple is well within applicable standards but may render further processing of a photovoltaic thin-layer module (e.g. in plasma enhanced chemical vapour deposition (PECVD)) impossible especially if the electrode-to-substrate spacing in the PECVD plant is small, or if laser structuring is used, as such ripple precludes the proper focusing of the laser beam.

For these reasons, it is the object of the invention to provide a glass panel coated with an electrically conductive transparent metal oxide which panel has a high flexural strength and a high thermal fatigue resistance and is cost-effective to manufacture, such panel for use as a starting material for making a photovoltaic module.

In accordance with the invention, this object is attained by the method characterized in claim 1. Claims 2 to 9 recite advantageous further developments of the inventive method. Claims 10 to 12 relate to a glass panel made in accordance with the inventive method and coated with an electrically conductive transparent metal oxide. Claim 13 relates to a chemical vapour deposition plant for performing the inventive method.

In accordance with the inventive method, a glass panel cut to the final size required for the desired photovoltaic module is supplied to the plant where it is to be coated with the electrically conductive transparent metal oxide by chemical vapour deposition.

In the coating process, the glass panel has in the plant a coating temperature corresponding at least approximately to the transition temperature Tg of the glass.

The glass panel may be soda lime glass, borosilicate glass or another glass. As an electrically conductive transparent metal oxide, the material to be deposited on the glass panel may be tin oxide (SnO₂), especially fluorine-doped tin oxide (SnO₂:F), or zinc oxide (ZnO), for example.

The coating of the glass panel with the electrically conductive transparent metal oxide at a coating temperature corresponding to the transition temperature Tg is performed preferably by chemical vapour deposition at atmospheric pressure (APCVD process). Thus, an APCVD plant is used which is configured to get the coating temperature of the glass panel to be near the transition temperature Tg of the glass.

The coating temperature should be not more than 50° C., preferably not more than 30° C., and most preferably not more than 20° C. below the transition temperature Tg of the glass.

The glass panels conventionally used for photovoltaic modules, which are made of soda lime glass or the like, are heated to a coating temperature of more than 540° C., especially more than 570° C., whereupon the coating of the electrically conductive transparent metal oxide is applied by chemical vapour deposition.

Surprisingly, the high coating temperature results in improved conductivity of the electrically conductive transparent metal oxide layer without increasing optical absorption in the IR range.

Right after having been coated with the electrically conductive transparent metal oxide, the glass panel is cooled down quickly from the coating temperature near the transition temperature Tg. This causes the glass to be pre-stressed, resulting in a high flexural strength and a high temperature fatigue resistance thereof. For forming the desired pre-stress, when cooling the coated glass panel down from the coating temperature, the cooling rate should be at least 20 K/min. The preferable cooling rate is 20 K/min to 300 K/min, especially 50 K/min to 200 K/min. This cooling rate is maintained until the glass panel coated with the electrically conductive transparent metal oxide has cooled to at least 450° C.

In the process, the cooling-down is obtained preferably by blowing air or another gas onto both sides of the glass panel coated with the electrically conductive transparent metal oxide.

It is preferred in accordance with the invention to coat glass panels of 3 mm to 6 mm thickness. In the case of greater thicknesses, the plant should be set to lower cooling rates than for lesser thicknesses.

Depending on the type of glass (soda lime glass, borosilicate glass or the like) and the thickness of the glass panel, the coating temperature and the cooling rate may be set to impart to the coated glass panel a flexural strength of more than 120 N/mm², i.e. a flexural strength corresponding to that of single-layer safety glass.

However, the cooling rate is preferably set in dependence on the coating temperature, the type of glass and the thickness of the glass panel to obtain a flexural strength of 50 N/mm² to 120 N/mm², especially 60 N/mm² to 100 N/mm², with the flexural strength determined according to test standard EN 1288-3.

With the cooling rate set to obtain a flexural strength lower than 120 N/mm², the ripple of the glass panel may be reduced to values below 1 mm per meter, especially 0.8 mm per meter and even less than 0.5 mm per meter.

In accordance with the invention, a photovoltaic thin-layer module may be structured to extreme precision by using a laser, for example, with the semiconductor layer applied by means of a PECVD plant featuring a very small electrode-substrate spacing.

At the same time, the inventive high coating temperature near the transition temperature Tg of the glass and the rapid cooling of the coated glass panel, result in a high temperature fatigue resistance of more than 50 K, especially more than 70 K. Regarding the flexural strength and the temperature fatigue resistance of the partly pre-stressed glass obtained in accordance with the invention, attention is directed to standard EN 1863.

On the basis of the high coating temperature near glass transition temperature Tg, the invention results preferably in a partly pre-stressed glass panel coated with a superior, electrically conductive transparent metal oxide layer. The rapid cooling following the coating treatment of the glass panel results in a high flexural strength, a high temperature fatigue resistance and a ripple substantially lower than that of a glass thermally pre-stressed in accordance with the applicable standard.

Made in accordance with the invention and coated with the electrically conductive transparent metal oxide, the inventive glass panel constitutes the starting material for fabricating a photovoltaic module. To this end, the glass panel coated with an electrically conductive transparent metal oxide in accordance with the invention is coated with a semiconductor layer and a rear electrode layer and is then treated between the application of said coatings with a laser so as to form an integrated series connection of the various solar cells, is provided with terminals and is finally laminated with a rear-surface protection which in turn may be a glass panel or a plastic film. The semiconductor layer may be silicon (amorphous, nanocrystalline or polycrystalline silicon) or another semiconductor (e.g. cadmium/tellurium).

The invention is explained in greater detail hereinafter under reference to the attached drawing, of which the only FIGURE schematically shows the preparation of a glass panel coated with an electrically conductive transparent metal oxide for making a photovoltaic module.

As shown in the FIGURE, a glass panel 1 cut to the desired size of the photovoltaic module is supplied to a plant 2 for the chemical vapour deposition of the electrically conductive transparent metal oxide 3 at a coating temperature corresponding to the transition temperature Tg of the glass. The glass panel 1 exiting from plant 2 and coated with the electrically conductive transparent metal oxide layer has a gas 4 blown there onto on both sides and is quenched thereby.

1. A method of making a glass panel (1) coated with an electrically conductive transparent metal oxide (3) for use as a starting material for making a photovoltaic module, characterized by a chemical vapour deposition of the electrically conductive transparent metal oxide (3) on glass panel (1) being performed at a coating temperature not more than 50° C. lower than the transition temperature of the glass.

2. Method as in claim 1, characterized in that the coating temperature at which chemical vapour deposition onto glass panel (1) is performed is not more than 20° C. lower than the transition temperature of the glass.

3. Method as in claim 1, characterized in that the glass panel (1) coated with the electrically conductive transparent metal oxide (3) is cooled down from the coating temperature with a cooling rate of at least 20 K/min.

4. Method as in claim 3, characterized in that the cooling rate is 50 K/min to 200 K/min.

5. Method as in claim 1, characterized in that the cooling with the cooling rate defined in claim 3 is performed until the glass panel (1) coated with said electrically conductive transparent metal oxide (3) has been cooled to at least 450° C.

6. Method as in claim 3, characterized in that said cooling-down is performed by blowing (4) onto both sides of the glass panel (1) coated with the electrically conductive transparent metal oxide (3).

7. Method of claim 1, characterized by said chemical vapour deposition being performed at atmospheric pressure.

8. Method as in claim 1, characterized by using a glass panel (1) three millimeters to six millimeters thick.

9. Method as in claim 1, characterized by coating glass panel (1) with tin oxide as said electrically conductive transparent metal oxide (3).

10. Glass panel made in accordance with claim 1, characterized by having a flexural strength of 50 N/mm² to 120 N/mm².

11. Glass panel made in accordance with claim 1, characterized by a waviness smaller than 1 mm per meter, especially smaller than 0.5 mm per meter.

12. Glass panel made in accordance with claim 1, characterized by having a temperature fatigue resistance higher than 50 K, especially higher than 70 K.

13. Chemical vapour deposition plant for performing the method of claim 1, characterized by being configured so that glass panel (1) when being coated with said electrically conductive transparent metal oxide (3) has a coating temperature not more than 50° C. lower than the transition temperature of the glass.
